(19) United States
(12) Patent Application Publication
(10) Pub. No.: US 2007/0057599 A1
(43) Pub. Date: Mar. 15, 2007

(54) Film bulk acoustic resonator and method for manufacturing the same

(75) Inventors: Takako Motai, Yokohama-shi (JP); Hironobu Shibata, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/430,053

(22) Filed: May 9, 2006

(30) Foreign Application Priority Data
Sep. 9, 2005 (JP) P2005-262101

(51) Int. Cl. H01L 41/08

(52) U.S. Cl. 310/324

(57) ABSTRACT

A film bulk acoustic resonator includes a substrate having a through hole which is defined by an opening on a bottom surface of the substrate opposed to a top surface thereof. A width of the opening is larger than that at the top surface. A bottom electrode is provided above the through hole and extended over the top surface. A piezoelectric film is disposed on the bottom electrode. A top electrode is disposed on the piezoelectric film so as to face the bottom electrode. A sealing plate is inserted from the bottom surface into the through hole so as to seal the opening.

### CROSS REFERENCE TO RELATED APPLICATIONS AND INCORPORATION BY REFERENCE

This application is based upon and claims the benefit of priority from prior Japanese Patent Application P2005-262101 filed on Sep. 9, 2005; the entire contents of which are incorporated by reference herein.

### BACKGROUND OF THE INVENTION

1. Field of the Invention

The present invention relates to a film bulk acoustic resonator located between cavities, and a method for manufacturing the same.

2. Description of the Related Art

Wireless technology has achieved remarkable development, and further development targeting high-speed wireless transmission is now in progress. At the same time, higher frequencies are more readily attainable, along with increases in the amount of transmittable information. With respect to more highly functional mobile wireless devices, there are strong demands for smaller and lighter components, and components such as filters previously embedded as discrete components are being integrated.

In light of these demands, one of components drawing attention in recent years is a filter utilizing a film bulk acoustic resonator (FBAR). The FBAR is a resonator using a resonance phenomenon of a piezoelectric material, similar to a surface acoustic wave (SAW) element. The FBAR is more suitable for a high frequency operation above 2 GHz, whereas a SAW element has problems handling the relevant frequency range. Since the FBAR uses the resonance of longitudinal waves in the thickness direction of a piezoelectric film, it is possible to drastically reduce the size of the element, especially the thickness thereof. In addition, it is relatively easy to fabricate the FBAR on a semiconductor substrate, such as silicon (Si). Accordingly, the FBAR can be easily integrated into a semiconductor chip.

The FBAR is provided with cavities above and below a capacitor, in which the piezoelectric film is sandwiched between a top electrode and a bottom electrode. A method for forming the cavities and a support structure of the capacitor sandwiched between the cavities are major issues in manufacturing techniques of the FBAR. Particularly, it is necessary to provide a cavity immediately below the bottom electrode of the capacitor, formed in the substrate. Therefore, the manufacturing techniques of the FBAR may be limited. Currently, a sacrificial layer etching process and a backside bulk etching process have been used for forming a cavity in the substrate.

In a FBAR manufactured by a sacrificial layer etching process, a groove provided on a surface of the substrate immediately below the bottom electrode is used as a cavity (refer to Japanese Unexamined Patent Publication No. 2000-69594). For example, a sacrificial layer is formed by burying the groove provided in the substrate. A capacitor and the like are formed on the sacrificial layer. Thereafter, the sacrificial layer is removed by selective etching to form the cavity. In the sacrificial layer etching process, the sacrificial layer must be completely removed through narrow openings. Accordingly, the sacrificial layer etching process may be one of the major reasons for a reduction in yields. However, the sacrificial layer etching process is effective for suppressing the thickness of the FBAR because it is usually unnecessary to seal the cavity after removing the sacrificial layer.

In a FBAR manufactured by a backside bulk etching process, a through hole is formed immediately below the bottom electrode, from the backside of the substrate. The through hole is used as a cavity (refer to U.S. Pat. No. 6,713,314). For example, after forming a capacitor and the like on the substrate, the through hole is formed by removing the substrate immediately below the bottom electrode, from the backside of the substrate, by reactive ion etching (RIE) or the like. The cavity is formed immediately below the bottom electrode by sealing the through hole from the backside of the substrate. In the backside bulk etching process, it is relatively easy to form the cavity. However, the FBAR becomes thicker due to a sealing substrate on the backside of the substrate. As a result, the backside bulk etching process has a disadvantage from a standpoint for packaging or integrating the FBAR.

As described above, in the case of a FBAR manufactured by the backside bulk etching process, it is necessary to decrease the thicknesses of the substrate for forming the capacitor, and the sealing substrate, in order to decrease the thickness of the FBAR. However, thinning the processing substrate causes a significant reduction in the strength of the substrate and the substrate may easily break during manufacturing processes. As a result, the manufacturing yield of the FBAR decreases. From a practical point of view, it is necessary to bond a reinforcing substrate temporarily to the substrate, after decreasing the thickness of the substrate for the FBAR less than about 300 μm. Due to such a bonding process and a process for removing the reinforcing substrate, manufacturing cost of the FBAR may inevitably increase, and cost competitiveness of the FBAR may be deteriorated.

### SUMMARY OF THE INVENTION

A first aspect of the present invention inheres in a film bulk acoustic resonator including a substrate having a through hole, the through hole being defined by an opening on a bottom surface of the substrate opposed to a top surface of the substrate, the opening having a width larger than an opening width at the top surface; a bottom electrode provided above the through hole and being extended over the top surface; a piezoelectric film disposed on the bottom electrode; a top electrode disposed on the piezoelectric film so as to face the bottom electrode; and a sealing plate provided at the bottom surface of the substrate, being inserted into the through hole so as to seal the opening.

A second aspect of the present invention inheres in a method for manufacturing a film bulk acoustic resonator including delineating a bottom electrode over a top surface of a substrate; stacking a piezoelectric film on the bottom electrode; delineating a top electrode on the piezoelectric film so as to face the bottom electrode; digging a through hole by selectively removing the substrate below the bottom electrode, from a bottom surface of the substrate opposed to the top surface, the through hole being defined by an opening width at the bottom surface of the substrate larger than an opening width at the top surface; and inserting a sealing plate from the bottom surface side into the through hole so as to seal a bottom portion of the through hole.

### BRIEF DESCRIPTION OF THE DRAWINGS

FIG. 1 is a plan view showing an example of a FBAR according to a first embodiment of the present invention.

FIG. 2 is cross-sectional view taken on line II-II of the FBAR shown in FIG. 1.

FIG. 3 is a graph showing an example of variation in the resonance characteristics of FBARs due to resin sealing.

FIGS. 4 to 12 are cross-sectional views showing an example of a method for manufacturing a FBAR according to the first embodiment of the present invention.

FIG. 13 is a cross-sectional view showing another example of a through hole of a FBAR according to the first embodiment of the present invention.

FIG. 14 is a cross-sectional view showing another example of a FBAR according to the first embodiment of the present invention.

FIG. 15 is a view showing an example of a FBAR according to a second embodiment of the present invention.

FIGS. 16 to 19 are cross-sectional views showing an example of a method for manufacturing a FBAR according to the second embodiment of the present invention.

FIG. 20 is a cross-sectional view showing another example of a FBAR according to the second embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

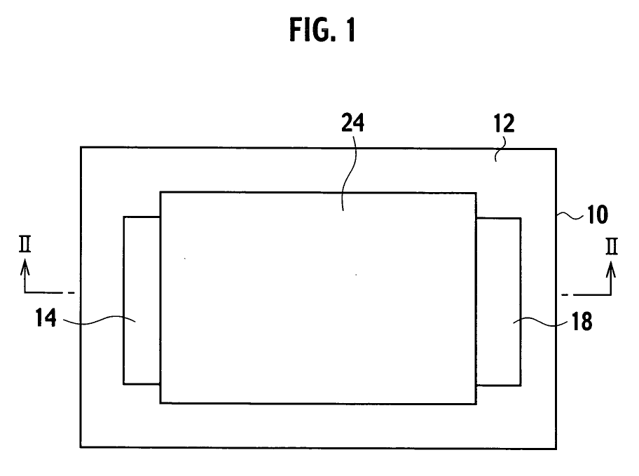

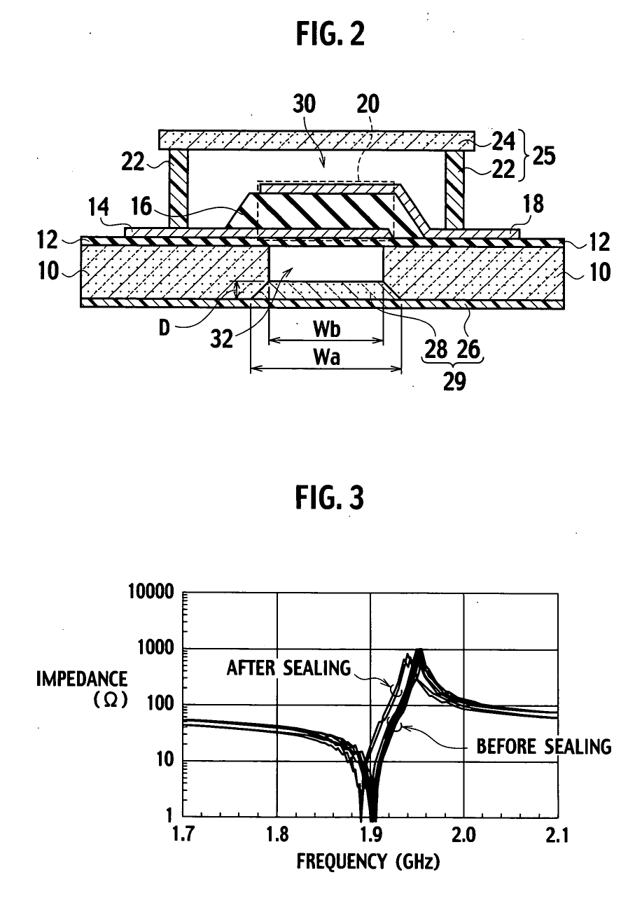

As shown in FIGS. 1 and 2, a FBAR according to a first embodiment of the present invention includes a substrate 10, a bottom electrode 14, a piezoelectric film 16, a top electrode 18, a top sealing member 25, a bottom sealing member 29, and the like. The substrate 10 has a through hole which is defined by an opening on a bottom surface of the substrate 10, opposed to a top surface of the substrate 10. The opening has a width larger than that at the top surface of the substrate 10. The bottom electrode 14 is disposed on an insulating film 12 formed on the top surface of the substrate 10. The bottom electrode 14 is provided above the through hole and extends over the top surface of the substrate 10. The piezoelectric film 16 is disposed on the bottom electrode 14. The top electrode 18 is disposed on the piezoelectric film 16 so as to face the bottom electrode 14. The top electrode 18 extends from a region above the piezoelectric film 16 to a region above the substrate 10. A capacitor 20, which serves as a resonator of the FBAR, is defined by a region in which the bottom electrode 14 and the top electrode 18 face each other to sandwich the piezoelectric film 16. The bottom and top electrodes 14, 18 implement capacitor electrodes of the capacitor 20.

The top sealing member 25 includes a supporting member 22 and a sealing plate 24. The supporting member 22 is disposed above the top surface side of the substrate 10 so as to surround the capacitor 20. The sealing plate 24 is disposed on the supporting member 22 so as to form a cavity 30 above the capacitor 20 and to seal the capacitor 20.

The bottom sealing member 29 includes a sealing plate 28 and a supporting film 26. The sealing plate 28, which is provided at the bottom surface of the substrate 10, is inserted into the through hole so as to form a cavity 32 below the capacitor 20 and to seal a bottom portion of the through hole provided in the bottom surface of the substrate 10. The supporting film 26 is provided so as to cover a bottom surface of the sealing plate 28 and the bottom surface of the substrate 10.

In the capacitor 20, a high-frequency signal is transmitted by resonance of a bulk acoustic wave of the piezoelectric film 16. The piezoelectric film 16 is excited by the high-frequency signal applied to the bottom electrode 14 or the top electrode 18. In order to achieve a resonance frequency in a desired GHz frequency band, the thickness of the piezoelectric film 16 is determined by considering the weight of the bottom electrode 14 and the top electrode 18 in the capacitor 20.

To achieve a fine resonance characteristic from the capacitor 20, an AlN film or a ZnO film, which has excellent film quality including crystal orientation and uniformity of film thickness, may be used as the piezoelectric film 16. A metal film, such as aluminum (Al), molybdenum (Mo), or tungsten (W), may be used as the bottom electrode 14 and the top electrode 18. The substrate 10 may be a semiconductor substrate, such as Si. A silicon oxide (SiO₂) film and the like may be used as the insulating film 12. A photosensitive resin and the like may be used as the supporting member 22. An organic material, such as polyimide, may be used as the supporting film 26. A semiconductor substrate, such as Si, may be used as the sealing plates 24 and 28.

In the FBAR according to the first embodiment, the bottom portion of the through hole has slanted sidewalls that extend from the bottom surface to a depth D in the bottom surface side of the substrate 10. The opening width of the through hole has a maximum value Wa on the bottom surface. The cavity 32, which corresponds to a top portion of the through hole in the top surface side of the substrate 10, has a substantially vertical sidewall with an opening width Wb. A cross-sectional shape of the sealing plate 28, perpendicular to the top surface of the substrate 10, is a trapezoid having a lower base approximately equal to Wa, an upper base approximately equal to Wb, and a height approximately equal to D. A tilt angle of side ends of the trapezoid is substantially equal to a tilt angle of the slanted sidewalls in the bottom portion of the through hole. Therefore, the sealing plate 28 is complementarily fitted to the slanted sidewall of the through hole. As a result, the thickness of the FBAR, due to the bottom sealing member 29, can be substantially suppressed to only the thickness of the supporting film 26.

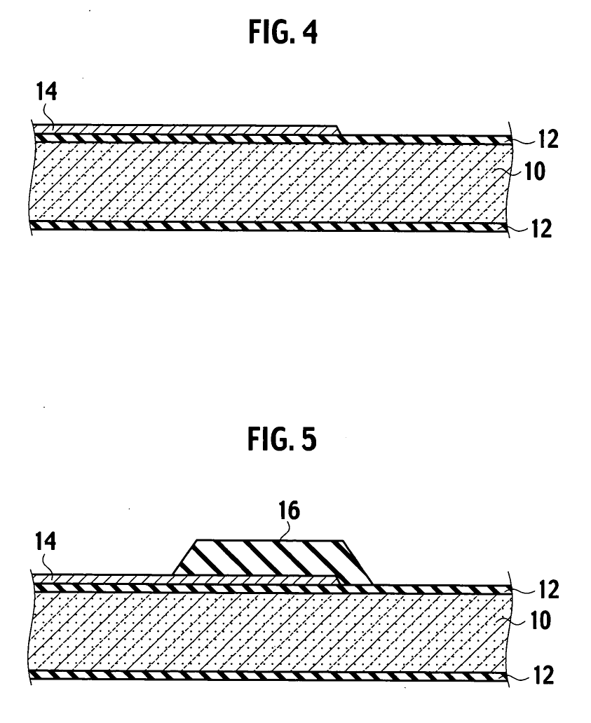

In usual plastic sealing, a thermosetting resin is used as an adhesive, for example. When a thin film sheet sealing member, which is an organic material similar to the supporting film 26, is exposed directly in the through hole, or when a sealing substrate sealing member is attached to the bottom surface of the flat substrate 10 using an adhesive, a part of the resin may leak into the interior of the cavity 32 or a volatile component of the adhesive maybe diffused in the cavity 32. As a result, as shown in FIG. 3, resonance characteristics of FBARs before sealing may be changed after sealing. As described above, it is not possible to provide a desired stable resonance frequency of a FBAR, and thus the manufacturing yield of the FBAR is decreased.

In the first embodiment, the cavity 32 formed below the capacitor 20 is hermetically sealed by the sealing plate 28. Therefore, by plastic sealing using the bottom sealing member 29, it is possible to prevent a part of the resin from leaking into the interior of the cavity 32 and from diffusing a volatile component of the adhesive inside the cavity 32. As a result, it is possible to suppress variations of the resonance frequency of the FBAR and decrease in the manufacturing yield thereof.

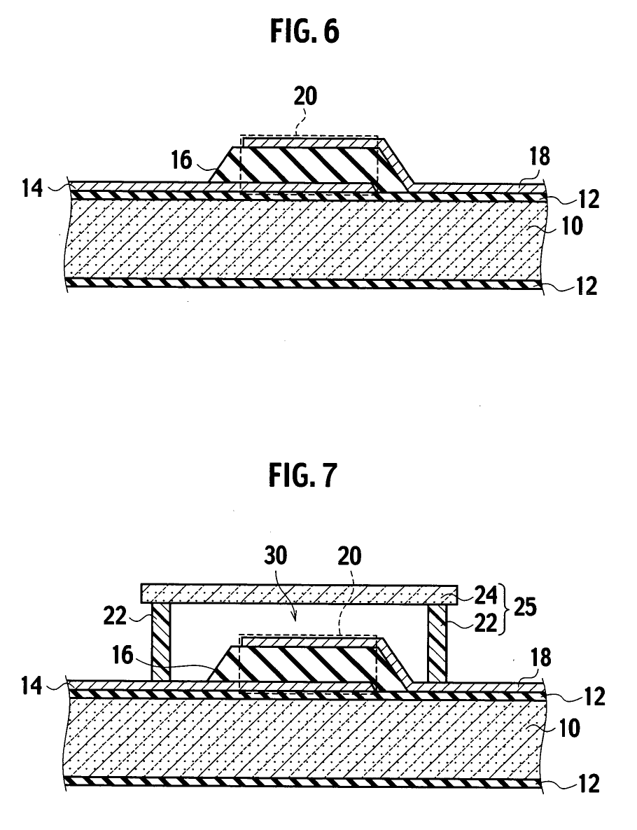

Next, a method for manufacturing a FBAR according to the first embodiment of the present invention will be described with reference to cross-sectional views shown in FIGS. 4 to 12. Here, each of the cross-sectional views used for describing the manufacturing method corresponds to across-section taken along the line II-II shown in FIG. 1.

As shown in FIG. 4, an insulating film 12 are formed on top and bottom surfaces of a substrate 10, such as a single crystal Si substrate, by thermal oxidation and the like. The substrate 10 has a (100) plane orientation and a thickness of about 675 μm, for example. The insulating film 12, such as SiO₂, has a thickness of about 200 nm. A metal film, such as Mo, is deposited on the insulating film 12 on the top surface of the substrate 10 with a thickness range from about 150 nm to about 600 nm, desirably with a thickness range from about 250 nm to about 350 nm, by direct-current (DC) magnetron sputtering and the like. The metal film is selectively removed by photolithography, RIE and the like to delineate a bottom electrode 14.

As shown in FIG. 5, a wurtzite-type AlN film is deposited with a thickness of about 0.5 μm to about 3 μm on the top surface of the substrate 10 on which the bottom electrode 14 has been formed. The thickness of the AlN film is determined by a resonance frequency. For example, when the resonance frequency is about 2 GHz, the thickness of the AlN film is about 2 μm. The AlN film is selectively removed by photolithography, RIE using a chloride gas, and the like to stack a piezoelectric film 16 on the surface of the bottom electrode 14.

As shown in FIG. 6, a metal film, such as Al, is deposited on the top surface of the substrate 10 on which the piezoelectric film 16 has been formed with a thickness range from about 150 nm to about 600 nm, desirably with a thickness range from about 250 nm to about 350 nm by DC sputtering and the like. The metal film is selectively removed by photolithography, wet etching using a non-oxidizing acid such as hydrochloric acid, and the like, to delineate a top electrode 18 facing the bottom electrode 14 and sandwiching the piezoelectric film 16 therebetween. The capacitor 20 is defined in a region where the bottom electrode 14 and the top electrode 18 face each other.

As shown in FIG. 7, a resin film, such as a photosensitive resin, is spin-coated on the top surface of the substrate 10 on which the top electrode 18 has been formed. The resin film has a thickness from about 5 μm to about 20 μm, more specifically a thickness of about 10 μm, for example. A portion of the resin film, which is selectively cross-linked by photolithography and the like, is retained to form a supporting member 22 so that the capacitor 20 is situated inside the supporting member 22. A sealing plate 24, such as Si, having a thickness of about 100 μm is placed on the supporting member 22. A thermosetting resin, such as epoxy resin, having a thickness of about 1 μm is coated on the sealing plate 24. The sealing plate 24 is attached to the supporting member 22 by heating. The cavity 30 surrounded by the top sealing member 25 including the supporting member 22 and the sealing plate 24 is formed above the capacitor 20.

As shown in FIG. 8, the thickness of the substrate 10 is reduced to about 300 μm, for example, by grinding from the bottom surface of the substrate 10. The substrate 10 is selectively removed from the bottom surface thereof by photolithography, anisotropic etching using a potassium hydroxide (KOH) solution, and the like, to dig a trench 50 having slanted sidewalls. The trench 50 has an opening width Wa at the bottom surface of the substrate 10 and a depth of about 200 μm. In anisotropic etching, a {100} plane and a {110} plane are selectively etched and the etching rate in a <111>direction is small. Therefore, each of the slanted sidewalls formed by anisotropic etching is substantially a {111} plane. As a result, a tilt angle α of each sidewall of the trench 50 with respect to the bottom surface of the substrate 10 is close to an angle of 54.74° between the {100} and {111} planes. Here, the anisotropic etching is not limited only to KOH etching. It is also possible to use a tetramethylammonium hydroxide (TMAH) solution, an ethylene diamine pyrocatechol (EDP) solution, and the like.

As shown in FIG. 9, the substrate 10 is selectively removed with an opening width Wb, which is smaller than the opening width Wa, from a base of the trench 50, which has the slanted sidewalls, while using the insulating film 12 as an etching stopper layer, so as to dig a groove having vertical sidewalls. Thereafter, the insulating film 12 below the capacitor 20 is selectively removed by wet etching, chemical dry etching (CDE) and the like, to form a through hole 54. A bottom portion of the sidewalls of the through hole 54 in the bottom surface side of the substrate 10 are slanted at the angle α. A top portion of the sidewalls in the top surface side of the substrate 10 are substantially vertical.

Thereafter, a resonance frequency of the FBAR is measured. When the measured resonance frequency is less than a desired resonance frequency, a film thickness of the bottom electrode 14 is decreased by etching with a chlorine (Cl) containing gas and the like from the through hole 54. At this time, it is possible to very accurately decrease the film thickness of the bottom electrode 14 by adjusting the temperature of the bottom electrode 14 while irradiating an infrared light and the like. By reducing the weight of the bottom electrode 14, the resonance frequency is shifted to a higher frequency. Thus, the desired resonance frequency can be achieved. On the contrary, when the measured resonance frequency is higher than the desired resonance frequency, the bottom surface of the bottom electrode 14 is increased by plating with a copper (Cu) plating solution and the like from the through hole 54. The weight of the bottom electrode 14 is increased by plating, and the resonance frequency is shifted to a lower frequency. Thus, the desired resonance frequency can be achieved.

As shown in FIG. 10, a supporting film 26, such as polyimide, which has a thickness equal to about 100 μm or less, is prepared. A substrate 28a, such as a single crystal Si substrate, which has a (100) plane orientation the same as the substrate 10 and a thickness of about 200 μm, is attached to the supporting film 26. A resist pattern 56 is delineated on a surface of the substrate 28a by photolithography and the like. The width of the resist pattern 56 is made substantially equal to the opening width Wa.

As shown in FIG. 11, the substrate 28a is selectively removed by anisotropic etching with a KOH solution and the like, while using the resist pattern 56 as a mask, to form a bottom sealing member 29. The bottom sealing member 29 includes the supporting film 26 and a sealing plate 28 disposed on the supporting film 26. The sealing plate 28 is shaped so that a cross-sectional shape perpendicular to the top surface of the substrate 10 is a trapezoid. Each of slanted sidewalls of the sealing plate 28, formed by anisotropic etching, is substantially a {111} plane. The width of a lower base of the sealing plate 28 contacting the supporting film 26 is approximately equal to Wa. A tilt angle β of each sidewall with respective to the surface of the sealing plate 28 is substantially equal to the angle α of each sidewall of the through hole 54.

As shown in FIG. 12, an adhesive, such as thermosetting resin, is coated on the bottom surface of the substrate 10. The supporting film 26 of the bottom sealing member 29 is attached to the bottom surface of the substrate 10 by heating. The sealing plate 28 is inserted from the bottom surface side of the substrate 10 into the through hole 54 so as to seal the bottom portion of the through hole 54 and to form a cavity 32. Thus, the FBAR according to the first embodiment is manufactured.

In the first embodiment, the tilt angle a of the side walls in the bottom surface side of the through hole 54, formed in the substrate 10, is substantially equal to the tilt angle β of the side walls of the sealing plate 28. In particular, when the substrate 10 and the substrate 28a are the same semiconductor material, it is possible to make the tilt angle α substantially equal to the tilt angle β provided by anisotropic etching. Moreover, the width of the lower base of the sealing plate 28 is substantially equal to the opening width Wa of the through hole 54. Therefore, each sidewall of the sealing plate 28 is complementary fitted to each slanted sidewall of the through hole. As a result, it is possible to suppress an increase of a thickness of the FBAR to only the thickness of the supporting film 26, due to attachment of the bottom sealing member 29.

Moreover, the cavity 32, formed below the capacitor 20, is hermetically sealed by the sealing plate 28. Therefore, when sealing the bottom sealing member 29 using a resin, it is possible to prevent leakage of the resin and diffusion of a volatile component of the resin into the interior of the cavity 32. As a result, it is possible to suppress variations of a resonance frequency of the FBAR and reduction of manufacturing yield.

As described above, in the method for manufacturing a FBAR according to the first embodiment, it is possible to prevent an increase in the thickness of the FBAR due to the bottom sealing member 29, and to accurately adjust the resonance frequency. As a result, it is possible to prevent a decrease in the manufacturing yield of the FBAR.

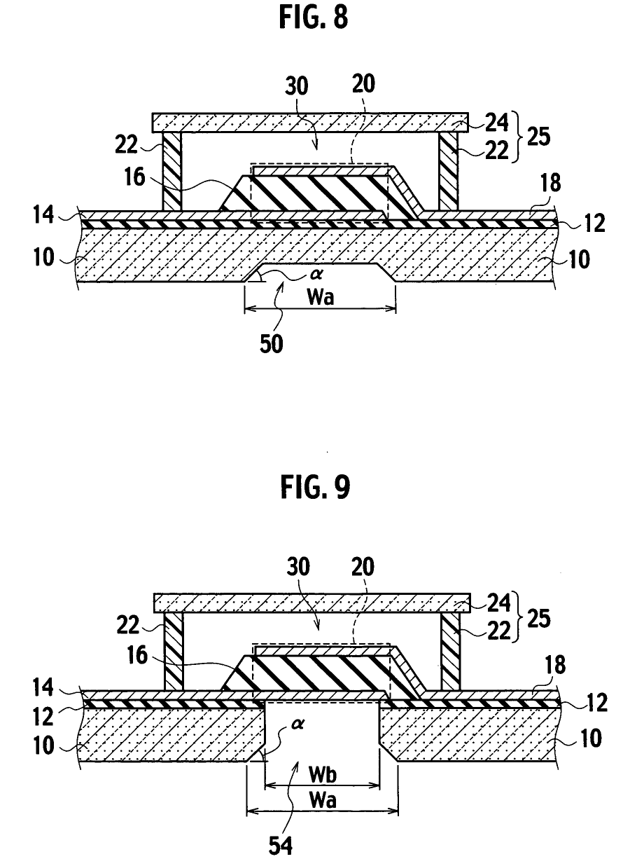

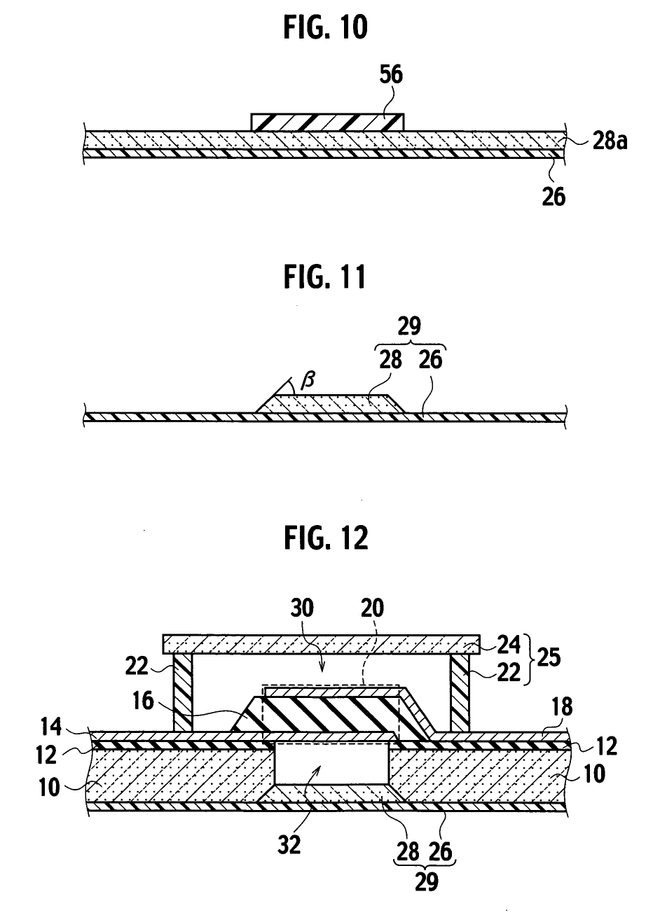

In the first embodiment, each sidewall of the cavity 32 in a cross-section perpendicular to the top surface of the substrate 10 is vertical. However, the cross-section of each sidewall of the cavity 32 may be an arbitrary shape. For example, as shown in FIG. 13, a through hole 54a may be formed with sidewalls which are slanted from the bottom surface of the substrate 10 to the top surface contacting the insulating film 12. The through hole 54a can be formed by selectively removing the substrate 10 until reaching the insulating film 12 in the etching process for the trench 50, shown in FIG. 8. Alternatively, the through hole 54a can be formed by using anisotropic etching in the etching process for the through hole 54, shown in FIG. 9. As shown in FIG. 14, a cavity 32a which is hermetically sealed by the sealing plate 28 is formed below the capacitor 20 by attaching the bottom sealing member 29, shown in FIG. 11, to the through hole 54a.

Moreover, in the above description, the width of the resist pattern 56 for forming the sealing plate 28 is substantially equal to the opening width Wa of the trench 50 or the through hole 54. However, it is desirable for the width of the resist pattern 56 smaller than the opening width Wa in consideration of a processing error of the resist pattern 56 or the sealing plate 28. Since the supporting film 26 is flexible, it is possible to hermetically seal the cavity 32 with the sealing plate 28 by pushing the sealing plate 28 into the through hole 54 until each sidewall of the sealing plate 28 contacts each sidewall of the through hole 54, even when the formed sealing plate 28 has a lower base which is slightly smaller than the opening width Wa.

### Second Embodiment

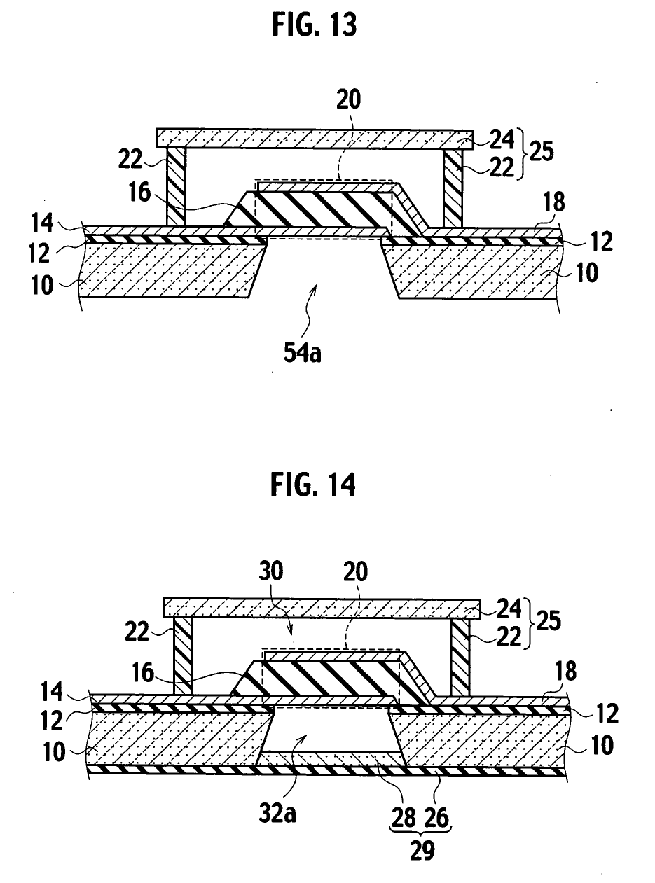

As shown in FIG. 15, a FBAR according to a second embodiment of the present invention includes a substrate 10, a bottom electrode 14, a piezoelectric film 16, a top electrode 18, a top sealing member 25, a bottom sealing member 29a, and the like. A through hole including a cavity 32 has substantially vertical sidewalls. Step portions are provided in the through hole so that an opening width at a bottom surface side of the substrate 10 is larger than an opening width of the cavity 32. A sealing plate 28b of the bottom sealing member 29a is inserted in the through hole to form the cavity 32 below the capacitor 20. Across-sectional shape of sealing plate 28b, perpendicular to the top surface of the substrate 10, is a rectangle. Each sidewall of the sealing plate 28b is substantially vertical. The width of the sealing plate 28b is larger than that of the cavity 32. The sealing plate 28b is provided on a supporting film 26.

The FBAR according to the second embodiment is different from the structure of the FBAR according to the first embodiment in that the through hole is sealed by the bottom sealing member 29a including the sealing plate 28b having the substantially vertical sidewalls to form the cavity 32. Other features are substantially the same as the first embodiment, so duplicated descriptions are omitted.

In the FBAR according to the second embodiment, the sealing plate 28b is complementary fitted to the bottom portion of the through hole in the bottom surface side of the substrate 10 that has the larger opening width than that of the cavity 32. A top surface of the sealing plate 28b contacts the step portions of the through hole so as to hermetically seal the cavity 32. Therefore, it is possible to prevent an increase of the thickness due to the bottom sealing member 29a and to accurately adjust a resonance frequency of the FBAR. As a result, it is possible to prevent a decrease in the manufacturing yield of the FBAR.

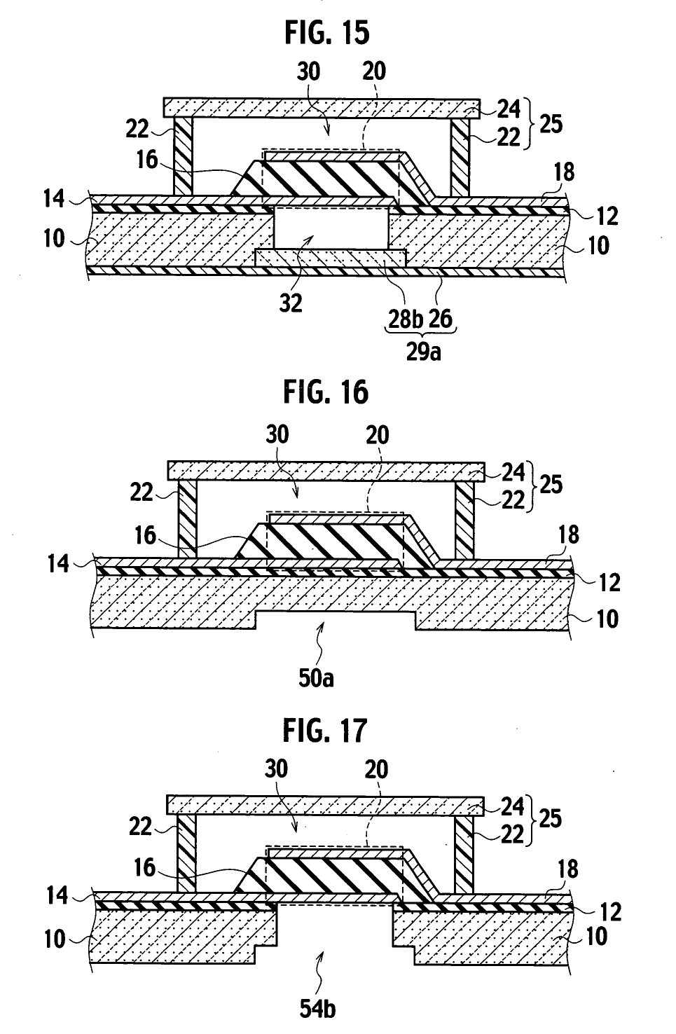

Next, a method for manufacturing a FBAR according to the second embodiment of the present invention will be described with reference to cross-sectional views shown in FIGS. 16 to 19. Here, the manufacturing processes shown in FIGS. 4 to 7 have been carried out, similar to the first embodiment in advance.

As shown in FIG. 16, the thickness of the substrate 10 is reduced to about 300 μm, for example, by grinding the bottom surface of the substrate 10. The substrate 10 is selectively removed from the bottom surface of the substrate 10 by photolithography, RIE and the like, to dig a trench 50a having substantially vertical sidewalls. The depth of the trench 50a is about 200 μm, for example.

As shown in FIG. 17, the substrate 10 is provided with an opening having a width, which is smaller than the opening width of the trench 50a. The opening is provided by selectively removing the substrate 10, by photolithography, RIE or the like, from a base plane of the trench 50a while using the insulating film 12 as an etching stopper layer. Thereafter, the insulating film 12 below the capacitor 20 is selectively removed by wet etching, CDE and the like, to form a through hole 54b. Sidewalls of the through hole 54b are substantially vertical, and step portions are formed between the bottom and top surfaces of the substrate 10. Thereafter, a resonance frequency of the FBAR is adjusted to a desired value by processing the bottom electrode 14 of the FBAR.

As shown in FIG. 18, a supporting film 26, such as polyimide, having a thickness equal to about 100 μm or less, is prepared. A substrate 28a, such as a single crystal Si substrate, having a thickness of about 200 μm, is attached to the supporting film 26. A resist pattern 56 is delineated on a surface of the substrate 28a by photolithography and the like. The width of the resist pattern 56 is smaller than the opening width of the through hole 54b at the bottom surface side of the substrate 10, due to consideration of a possible processing error.

As shown in FIG. 19, the substrate 28a is selectively removed by RIE and the like, using the resist pattern 56 as a mask, to form a bottom sealing member 29a. The bottom sealing member 29a includes the supporting film 26 and a sealing plate 28b having a rectangular cross-sectional shape on the supporting film 26. A width of the sealing plate 28b is smaller than the opening width of the through hole 54b at the bottom surface side of the substrate 10.

An adhesive, such as thermosetting resin, is coated on the bottom surface of the substrate 10. The supporting film 26 of the bottom sealing member 29a is attached to the bottom surface of the substrate 10 by heating. The sealing plate 28b is inserted in the through hole 54b so as to form the cavity 32. Thus, the FBAR shown in FIG. 15 is manufactured.

In the second embodiment, the sealing plate 28b is complementary fitted to the bottom portion of the through hole 54b. As a result, it is possible to prevent an increase in the thickness of the FBAR to only the thickness of the supporting film 26, due to attaching the bottom sealing member 29a.

Moreover, a top surface of the sealing plate 28b contacts the step portions of the through hole 54b so as to hermetically seal the cavity 32. Therefore, when sealing the bottom sealing member 29a using a resin, it is possible to prevent leakage of the resin and diffusion of a volatile component into the interior of the cavity 32. As a result, it is possible to prevent variations of the resonance frequency of the FBAR and to prevent a decrease in the manufacturing yield.

As described above, in the method for manufacturing the FBAR according to the second embodiment, it is possible to prevent an increase in the thickness, due to the bottom sealing member 29a, and to accurately adjust the resonance frequency of the FBAR.

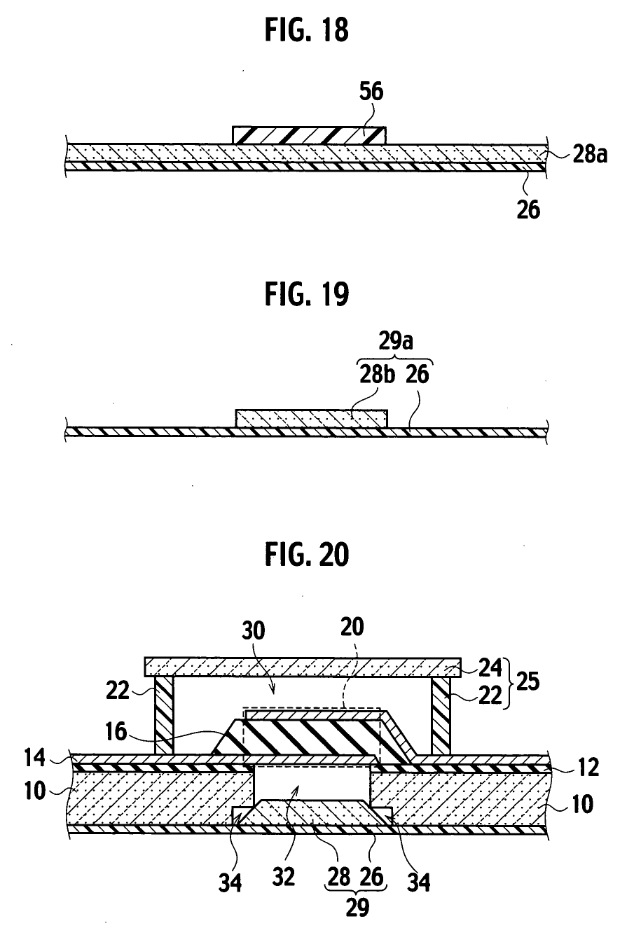

Furthermore, it is also possible to seal the through hole 54b, provided with the step portions, by the sealing plate 28 provided with the slanted sidewalls, as shown in FIG. 11. For example, as shown in FIG. 20, the cavity 32 may be hermetically sealed by the sealing plate 28 by adjusting the dimensions of the sealing plate 28 so that the slanted sidewalls of the sealing plate 28 contact edges of the step portions provided between the step portions and the sidewalls of the cavity 32. In this case, an air gap 34 is formed in the bottom surface side of the substrate 10. The air gap 34 can store the resin squeezed out during the pressing of the bottom sealing member 29a to attach the supporting film 26 to the bottom surface of the substrate 10. Thus, it is possible to prevent leakage of the resin into the interior of the cavity 32.

### Other Embodiments

In the first embodiment of the present invention, the sealing plate 28 includes slanted sidewalls which are complementary to the slanted sidewalls in the bottom portion of the through hole 54. However, the sidewalls of the sealing plate are not limited to only the complementary slanted sidewalls. For example, for the sidewalls of the sealing plate, vertical sidewalls are also within the scope of the invention. Moreover, it is also possible to form a sealing plate so as to have slanted sidewalls with a larger angle than the tilt angle of the slanted sidewalls of the through hole 54. For example, when using the sealing plate 28b, shown in FIG. 19, a cavity may be hermetically sealed by the sealing plate 28b so that an edge of the top surface of the sealing plate 28b contacts the slanted sidewalls of the through hole 54 shown in FIG. 9.

Various modifications will become possible for those skilled in the art after storing the teachings of the present disclosure without departing from the scope thereof.

What is claimed is:

1. A film bulk acoustic resonator, comprising:
a substrate having a through hole, the through hole being defined by an opening on a bottom surface of the substrate opposed to a top surface of the substrate, the opening having a width larger than an opening width at the top surface;
a bottom electrode provided above the through hole and being extended over the top surface;
a piezoelectric film disposed on the bottom electrode;
a top electrode disposed on the piezoelectric film so as to face the bottom electrode; and
a sealing plate provided at the bottom surface of the substrate, being inserted into the through hole so as to seal the opening.

2. The film bulk acoustic resonator of claim 1, wherein the through hole has slanted sidewalls at a bottom portion of the through hole.

3. The film bulk acoustic resonator of claim 1, wherein the through hole includes a bottom portion having slanted sidewalls and a top portion having vertical sidewalls.

4. The film bulk acoustic resonator of claim 1, wherein the through hole has substantially vertical sidewalls at a bottom portion of the through hole.

5. The film bulk acoustic resonator of claim 1, wherein the through hole includes a bottom portion and a top portion both having vertical sidewalls, the bottom portion having an opening width larger than the top portion.

6. The film bulk acoustic resonator of claim 1, further comprising a supporting film covering a bottom surface of the sealing plate and the bottom surface of the substrate.

7. The film bulk acoustic resonator of claim 1, further comprising a top sealing member disposed above the top surface of the substrate so as to surround a capacitor region in which the bottom and top electrodes implement capacitor electrodes facing each other, and to seal the capacitor region.

8. The film bulk acoustic resonator of claim 2, wherein a cross-sectional shape of the sealing plate perpendicular to the top surface of the substrate is a trapezoid.

9. The film bulk acoustic resonator of claim 4, wherein a cross-sectional shape of the sealing plate perpendicular to the top surface of the substrate is a rectangle.

10. The film bulk acoustic resonator of claim 6, wherein the supporting film is made of an organic material.

11. The film bulk acoustic resonator of claim 8, wherein a tilt angle of side ends of the trapezoid is substantially equal to a tilt angle of the slanted sidewalls at the bottom portion of the through hole.

12. The film bulk acoustic resonator of claim 8, wherein The substrate and the sealing plate are made of single crystal silicon having a (100) plane orientation.

13. The film bulk acoustic resonator of claim 12, wherein the sidewalls at the bottom portion of the through hole and sidewalls of the sealing plate are substantially a {111} plane.

14. A manufacturing method for a film bulk acoustic resonator, comprising:
delineating a bottom electrode over a top surface of a substrate;
stacking a piezoelectric film on the bottom electrode;
delineating a top electrode on the piezoelectric film so as to face the bottom electrode;
digging a through hole by selectively removing the substrate below the bottom electrode, from a bottom surface of the substrate opposed to the top surface, the through hole being defined by an opening width at the bottom surface of the substrate larger than an opening width at the top surface; and
inserting a sealing plate from the bottom surface side into the through hole so as to seal a bottom portion of the through hole.

15. The manufacturing method of claim 14, wherein the sealing plate is shaped so that a cross-sectional shape of the sealing plate perpendicular to the top surface of the substrate is a trapezoid, the cross-sectional shape fits the bottom portion of the through hole, the bottom portion is shaped so as to include slanted sidewalls.

16. The manufacturing method of claim 14, wherein the through hole is sealed by attaching a supporting film to the bottom surface of the substrate, the supporting film extending from a bottom surface of the sealing plate.

17. The manufacturing method of claim 16, wherein the supporting film is made of an organic material.

18. The manufacturing method of claim 16, wherein the supporting film is attached to the bottom surface of the substrate by an adhesive.

19. The manufacturing method of claim 15, wherein the substrate and the sealing plate are made of single crystal silicon having a (100) plane orientation, and the sidewalls in the bottom portion of the through hole and sidewalls of the sealing plate are substantially a {111} plane.

20. The manufacturing method of claim 19, wherein the bottom portion of the through hole and the sealing plate is formed by anisotropic etching.
